(19) United States
(12) Patent Application Publication
(10) Pub. No.: US 2026/0309894 A1
(43) Pub. Date: Oct. 8, 2026

(54) OPTICAL MEMBER, COVER WINDOW, AND ELECTRONIC DEVICE INCLUDING THE SAME

(71) Applicant: Samsung Display Co., Ltd., Yongin-si (KR)

(72) Inventors: Jongseok Joo, Yongin-si (KR); Taehee Kim, Yongin-si (KR); Hyunho Jeong, Yongin-si (KR)

(73) Assignee: Samsung Display Co., Ltd., Yongin-si (KR)

(21) Appl. No.: 19/563,557

(22) Filed: Mar. 11, 2026

(30) Foreign Application Priority Data
Apr. 4, 2025 (KR) 10-2025-0044317

(51) Int. Cl. G02B 1/115; G02B 1/14; G06F 1/16

(52) U.S. Cl. CPC G02B 1/115; G02B 1/14; G06F 1/1656

(57) ABSTRACT

An optical member and a cover window for a display device. The optical member includes three stacked units, each of which includes a high-refractive-index layer, and a low-refractive-index layer directly disposed on the high-refractive-index layer and having a lower refractive index than the high-refractive-index layer by about 0.3 or more, and among which the high-refractive-index layer of the second stacked unit has a thickness of about 250 nm to about 410 nm.

### CROSS-REFERENCE TO RELATED APPLICATIONS

This application claims priority under 35 U.S.C. § 119 to Korean Patent Application No. 10-2025-0044317, filed on Apr. 4, 2025, the entire contents of which are hereby incorporated by reference.

### BACKGROUND

The present disclosure herein relates to an optical member, a cover window, and an electronic device, and more particularly, to an optical member including a high-refractive-index layer and a low-refractive-index layer which are alternately stacked, a cover window including the optical member, and an electronic device including the cover window.

Multimedia electronic devices, such as a television, a mobile phone, a tablet computer, a navigation unit, and a game console, display images to a user through a display screen, and provide a touch-based input method that enables a user to input information or commands intuitively and conveniently. An electronic device may include a display module which generates an image, and a cover window for protecting the display module. It is required for the cover window to be configured to maintain excellent optical properties and a reliability in consideration of a using environment of the electronic device.

### SUMMARY

The present disclosure provides an optical member which has an excellent strength and a transparent color tone and functions to reduce reflection, and a cover window including the same.

The present disclosure also provides an electronic device including a display module, and a cover window which is disposed on the display module and includes an optical member having a transparent color tone, thereby exhibiting an excellent display quality.

An aspect of the present disclosure present disclosure provides an optical member including three stacked units, each of which includes a high-refractive-index layer, and a low-refractive-index layer directly disposed on the high-refractive-index layer and having a lower refractive index than the high-refractive-index layer by about 0.3 or more, wherein the three stacked units include a first stacked unit, a second stacked unit, and a third stacked unit which are stacked in a thickness direction, and the high-refractive-index layer of the second stacked unit has a thickness of about 250 nm to about 410 nm.

In an aspect, the high-refractive-index layer may include an Al—Si—N nanocomposite material, and the low-refractive-index layer may include a silicon oxide.

In an aspect, the high-refractive-index layer may have a Si content of about 5 at % to about 17 at %, and an O content of less than about 20 at %.

In an aspect, the high-refractive-index layer may have a refractive index of about 1.90 to about 2.30.

In an aspect, the low-refractive-index layer may have a refractive index of about 1.41 to about 1.54.

In an aspect, the first stacked unit may include a first high-refractive-index layer, and a first low-refractive-index layer directly disposed on the first high-refractive-index layer, the second stacked unit may include a second high-refractive-index layer directly disposed on the first low-refractive-index layer, and a second low-refractive-index layer directly disposed on the second high-refractive-index layer, the third stacked unit may include a third high-refractive-index layer directly disposed on the second low-refractive-index layer, and a third low-refractive-index layer disposed on the third high-refractive-index layer, the first high-refractive-index layer may have a thickness of about 15 nm to about 30 nm, the first low-refractive-index layer may have a thickness of about 18 nm to about 33 nm, the second low-refractive-index layer may have a thickness of about 5 nm to about 15 nm, the third high-refractive-index layer may have a thickness of about 130 nm to about 160 nm, and the third low-refractive-index layer may have a thickness of about 72 nm to about 98 nm.

In an aspect, the optical member may further include an anti-fingerprint layer directly disposed on an uppermost stacked unit among the stacked units, and having a thickness of about 10 nm to about 30 nm.

In an aspect, the optical member may have a residual stress of about 2 GPa or less at room temperature.

In an aspect of the present disclosure, a cover window includes: a base substrate; and an optical member including a first stacked unit, a second stacked unit, and a third stacked unit which are sequentially stacked on the base substrate, wherein the first to third stacked units each include a high-refractive-index layer, and a low-refractive-index layer directly disposed on the high-refractive-index layer and having a lower refractive index than the high-refractive-index layer by about 0.3 or more, and the high-refractive-index layer of the second stacked unit has a thickness of about 250 nm to about 410 nm.

In an aspect, the high-refractive-index layer may include an Al—Si—N nanocomposite material, and the low-refractive-index layer may include a silicon oxide.

In an aspect, the first stacked unit may include a first high-refractive-index layer, and a first low-refractive-index layer directly disposed on the first high-refractive-index layer, the second stacked unit may include a second high-refractive-index layer directly disposed on the first low-refractive-index layer, and a second low-refractive-index layer directly disposed on the second high-refractive-index layer, the third stacked unit may include a third high-refractive-index layer directly disposed on the second low-refractive-index layer, and a third low-refractive-index layer disposed on the third high-refractive-index layer, the first high-refractive-index layer may have a thickness of about 15 nm to about 30 nm, the first low-refractive-index layer may have a thickness of about 18 nm to about 33 nm, the second low-refractive-index layer may have a thickness of about 5 nm to about 15 nm, the third high-refractive-index layer may have a thickness of about 130 nm to about 160 nm, and the third low-refractive-index layer may have a thickness of about 72 nm to about 98 nm.

In an aspect, the high-refractive-index layer may have a refractive index of about 1.90 to about 2.30, and the low-refractive-index layer may have a refractive index of about 1.41 to about 1.54.

In an aspect, the cover window may have a maximum hardness of about 15 GPa or more which is measured through a Berkovich indentation hardness test on the basis of an indentation depth of about 50 nm or more.

In an aspect, the cover window may have an average transmittance of about 92% or more and an average SCI reflectance of about 8% or less within a wavelength range of about 400 nm to about 700 nm.

In an aspect, the cover window may have a color shift of about 2 or less for all viewing angles in the range of about 0° to about 60°, and the color shift may be calculated by the following equation 1:

$$color shift = \sqrt{{( {a}_{2}^{*} - {a}_{1}^{*} )}^{2} + {( {b}_{2}^{*} - {b}_{1}^{*} )}^{2}} \qquad [ Equation 1 ]$$

where in the equation 1, a*₁ and b*₁ may each represent a LAB color coordinate for normally incident light, and a*₂ and b*₂ may each represent a LAB color coordinate for incident light according to a viewing angle.

In an aspect of the present disclosure, an electronic device includes: a display module configured to generate an image; and a cover window disposed on the display module, wherein the cover window includes a base substrate disposed adjacent to the display module, and an optical member including a first stacked unit, a second stacked unit, and a third stacked unit which are sequentially stacked on the base substrate, and the first to third stacked units each include a high-refractive-index layer, and a low-refractive-index layer directly disposed on the high-refractive-index layer and having a lower refractive index than the high-refractive-index layer by about 0.3 or more, and the high-refractive-index layer of the second stacked unit has a thickness of about 250 nm to about 410 nm.

In an aspect, the first stacked unit may include a first high-refractive-index layer disposed on the base substrate, and a first low-refractive-index layer directly disposed on the first high-refractive-index layer, the second stacked unit may include a second high-refractive-index layer directly disposed on the first low-refractive-index layer, and a second low-refractive-index layer directly disposed on the second high-refractive-index layer, the third stacked unit may include a third high-refractive-index layer directly disposed on the second low-refractive-index layer, and a third low-refractive-index layer disposed on the third high-refractive-index layer, the first high-refractive-index layer may have a thickness of about 15 nm to about 30 nm, the first low-refractive-index layer may have a thickness of about 18 nm to about 33 nm, the second low-refractive-index layer may have a thickness of about 5 nm to about 15 nm, the third high-refractive-index layer may have a thickness of about 130 nm to about 160 nm, and the third low-refractive-index layer may have a thickness of about 72 nm to about 98 nm.

In an aspect, the cover window may have a maximum hardness of about 15 GPa or more, which is measured through a Berkovich indentation hardness test on the basis of an indentation depth of about 50 nm or more, and an average transmittance of about 92% or more and an average SCI reflectance of about 8% or less within a wavelength range of about 400 nm to about 700 nm.

In an aspect, the high-refractive-index layer may have a refractive index of about 1.90 to about 2.30, and the low-refractive-index layer may have a refractive index of about 1.41 to about 1.54.

In an aspect, the electronic device may further include at least one of a power module, a processor, or a memory.

### BRIEF DESCRIPTION OF THE FIGURES

The accompanying drawings are included to provide a further understanding of the present disclosure, and are incorporated in and constitute a part of this specification. The drawings illustrate aspects of the present disclosure and, together with the description, serve to explain principles of the present disclosure. In the drawings:

FIG. 1 is a block diagram of an electronic device according to an aspect;

FIG. 2 is a schematic view of each of electronic devices according to an aspect;

FIG. 3 is a perspective view of an electronic device according to an aspect;

FIG. 4 is an exploded perspective view of an electronic device according to an aspect;

FIG. 5 is a cross-sectional view of a cover window according to an aspect; and

FIG. 6 is a cross-sectional view of an optical member according to an aspect.

### DETAILED DESCRIPTION

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the present disclosure. Similarly, a second element, component, region, layer or section could be termed a first element, component, region, layer or section. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, an optical member according to an aspect, a cover window according to an aspect, and an electronic device according to an aspect are described with reference to the drawings.

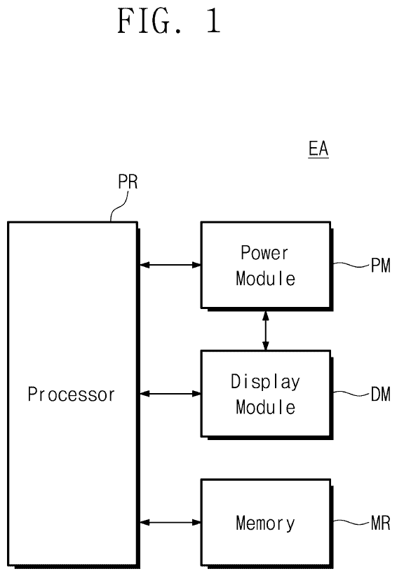

FIG. 1 is a block diagram of an electronic device according to an aspect. Referring to FIG. 1, an electronic device EA according to an aspect may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), or a controller.

The memory MR may store data information required for an operation of the processor PR or the display module DM. When the processor PR executes an application stored in the memory MR, image data signals and/or input control signals are transmitted to the display module DM, and the display module DM may process the transmitted signals to output image information through a display screen. The display module DM may include a display panel which displays an image.

The power module PM may include a power supply module, such as a power adapter or a battery device, and a power conversion module which converts power supplied from the power supply module to generate the power required for operation of the electronic device EA.

The electronic device EA may include a display device which generates and displays an image. The display device may include the display module DM. Additionally, some of the components or individual modules in the above-described electronic device EA may be included in the display device, and the others may also be provided separately from the display device. For example, the display device may include the display module DM, and the processor PR, the memory MR, and the power module PM may be provided in a form of another device in the electronic device EA other than the display device.

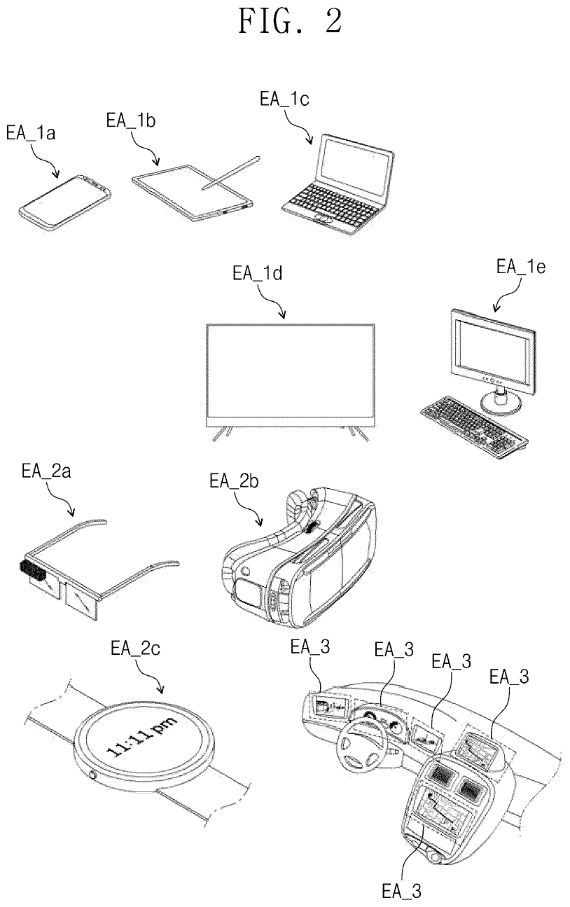

FIG. 2 is a schematic view of electronic devices according to various aspects.

Referring to FIG. 2, various electronic devices, including the display device according to an aspect, may include an electronic device for displaying images, such as a smart phone EA_1a, a tablet computer EA_1b, a laptop computer EA_1c, a television EA_1d, a desktop monitor EA_1e, and a wearable electronic device, such as a smart glasses EA_2a, a head mounted display EA_2b, a smart watch EA_2c, as well as an automobile electronic device EA_3, such as a center information display (CID) disposed on an instrument panel, a center fascia, or a dashboard of a car, and a room mirror display.

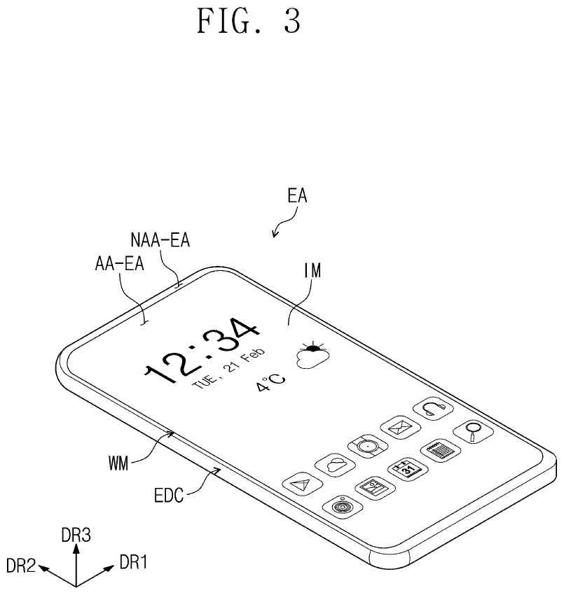

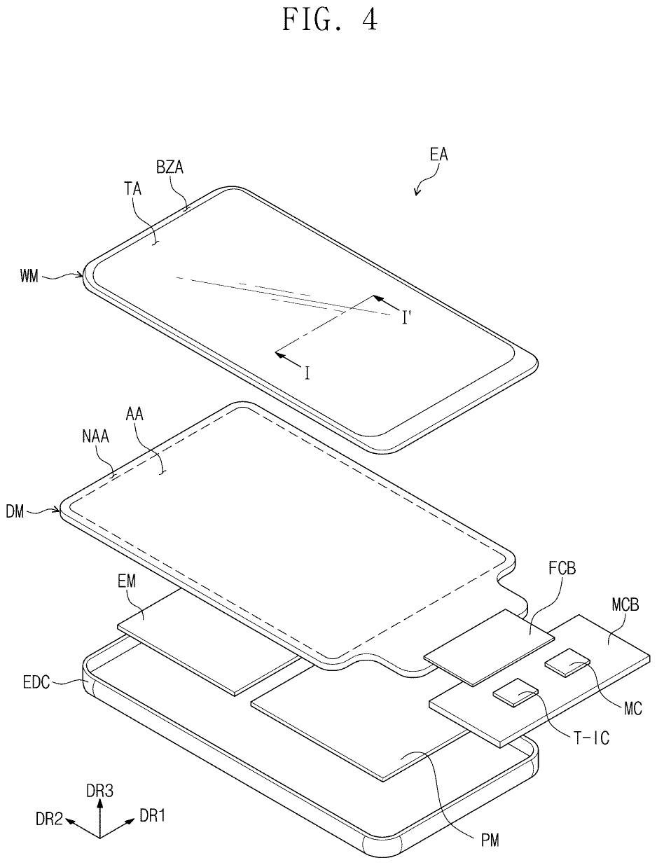

FIG. 3 is a perspective view illustrating an electronic device according to an aspect. FIG. 4 is an exploded perspective view of an electronic device according to an aspect.

FIG. 3 exemplarily illustrates an electronic device EA as a smart phone. However, the description, of the electronic device EA, made with reference to FIG. 3, etc. may also be similarly applied to other electronic devices.

The electronic device EA may be rigid or flexible. The term “flexible” means having a bendable property. For example, a flexible electronic device EA may include a curved device, a rollable device, or a foldable device.

In FIG. 3 and the following drawings, a first direction axis DR1 to a third direction axis DR3 are illustrated, and directions indicated by the first to third direction axes DR1, DR2, and DR3 described herein have a relative concept, and may thus be changed to other directions. In addition, the directions indicated by the first to third direction axes DR1, DR2, and DR3 may be referred to as first to third directions DR1, DR2, and DR3, and may be denoted as the same reference numerals or symbols. In this specification, the first direction axis DR1 and the second direction axis DR2 may be orthogonal to each other, and the third direction axis DR3 may be a normal direction of a plane defined by the first direction axis DR1 and the second direction axis DR2.

A thickness direction of the electronic device EA may be parallel to the third direction axis DR3 which is the normal direction of the plane defined by the first direction axis DR1 and the second direction axis DR2. In this specification, a front surface (or an upper surface) and a rear surface (or a lower surface) of each of members constituting the electronic device EA may be defined with respect to the third direction axis DR3. The front surface (or the upper surface) and the rear surface (or the lower surface) of each of members constituting the electronic device EA may be opposed to each other in the third direction DR3, and the normal direction of each of the front surface and the rear surface may be substantially parallel to the third direction DR3. A spacing distance between the front surface and the rear surface defined along the third direction DR3 may correspond to a thickness of a member.

In this specification, the wording “on a plane” may be defined as a state when viewed in the third direction DR3. In this specification, the wording “on a cross section” may be defined as a state when viewed in the first direction DR1 or the second direction DR2. The directions indicated by the first to third directions DR1, DR2, and DR3 have a relative concept, and may thus be changed to other directions.

The electronic device EA according to an aspect may display an image IM through an active region AA-EA. The active region AA-EA may include a flat surface defined by the first direction DR1 and the second direction DR2. The active region AA-EA may further include a curved surface bent from at least one side of the flat surface defined by the first direction DR1 and the second direction DR2. A surface, on which the image IM is displayed, may correspond to a front surface of the electronic device EA. The image IM may include a dynamic image as well as a static image.

A peripheral region NAA-EA is adjacent to the active region AA-EA. The peripheral region NAA-EA may surround the active region AA-EA. Accordingly, a shape of the active region AA-EA may be substantially defined by the peripheral region NAA-EA. However, this is exemplarily illustrated. The peripheral region NAA-EA may either be disposed adjacent to only one side of the active region AA-EA, or be omitted. The electronic device EA according to an aspect of the present disclosure may include active regions having various shapes, and is not limited to any one aspect.

On a plane, the electronic device EA may have a rectangular shape having short sides which extend in the first direction DR1, and long sides which extend in the second direction DR2 and cross the first direction DR1. However, the electronic device EA is not limited thereto, and may have various shapes, such as circular and polygonal shapes on a plane.

The electronic device EA may also detect an external input applied from the outside. The external input may include various forms of inputs such as force, pressure, temperature, and light.

Referring to FIGS. 3 and 4, an electronic device EA according to an aspect may include a display module DM, and a cover window WM according to an aspect disposed on the display module DM. The electronic device EA according to an aspect may further include an electronic module EM, a power module PM, a housing EDC, etc. Additionally, the electronic device EA according to an aspect may further include at least one of the processor PR (see FIG. 1) or the memory MR (see FIG. 1) in addition to the display module DM, and the power module PM which supplies power to the display module DM.

The display module DM may be configured to generate an image and detect an input applied from the outside. The display module DM according to an aspect may include components such as a display panel which generates an image, and an input sensor which detects pressure applied from the outside.

A display panel of the electronic device EA according to an aspect may be a light-emitting type display panel. For example, the display panel may be an organic light-emitting display panel, an inorganic light-emitting display panel, a quantum-dot display panel, a micro-LED display panel, or a nano-LED display panel. The display panel may be referred to as a display layer.

An active region AA and a peripheral region NAA may be defined in the display module DM. The active region AA may be activated in response to an electrical signal. The peripheral region NAA may be disposed adjacent to at least one side of the active region AA.

The active region AA may correspond to the active region AA-EA of the electronic device illustrated in FIG. 3. The peripheral region NAA may be disposed to surround the active region AA. However, an aspect is not limited thereto, and unlike what is illustrated in FIG. 4, etc., in an aspect, a portion of the peripheral region NAA may be omitted. The peripheral region NAA may correspond to the peripheral region NAA-EA of the electronic device illustrated in FIG. 3.

The display module DM according to an aspect may include the peripheral region NAA disposed in at least one side of the active region AA, and a driving circuit, a driving line, etc. for driving the active region AA may be disposed in a portion of the peripheral region NAA.

The display module DM may include a main circuit board MCB, and a flexible circuit film FCB which electrically connects the main circuit board MCB and the display module DM. Additionally, the main circuit board MCB may be electrically connected to the electronic module EM via a connector.

A sensor control circuit T-IC, a main controller MC, etc. may be disposed on the main circuit board MCB. The main controller MC may control an overall operation of the electronic device EA. For example, the main controller MC may control operations of the display panel, the input sensor, etc. Additionally, the main controller MC may control an operation of the electronic module EM. The main controller MC may include at least one microprocessor.

The flexible circuit film FCB may be connected to the display panel, the input sensor, etc., to electrically connect the display panel and input sensor and the main circuit board MCB. The input sensor may be electrically connected to the display panel, and also be electrically connected to the main circuit board MCB via the flexible circuit film FCB. However, an aspect is not limited thereto, and the input sensor may be electrically connected to the main circuit board MCB via an additional flexible circuit film. Alternatively, the flexible circuit film FCB may be omitted, and the main circuit board MCB may be directly connected to the display panel.

The electronic module EM may include various functional modules required for driving the electronic device EA. For example, the electronic module EM may include a wireless communication module, an image input module, a sound input module, a sound output module, a memory, an external interface module, etc. The above-described modules of the electronic module EM may be mounted on the main circuit board MCB, or may be electrically connected to the main circuit board MCB via an additional flexible circuit board.

The power module PM may be electrically connected to the electronic module EM. The power module PM may supply power required for overall operations of the electronic device EA. For example, the power module PM may include a typical battery device.

The cover window WM and the housing EDC may be coupled to each other to constitute the exterior of the electronic device EA. The cover window WM and the housing EDC may be coupled to form an inner space in which components of the electronic device EA are accommodated. The display module DM, the flexible circuit film FCB, the main circuit board MCB, the electronic module EM, the power module PM, etc., may be accommodated in the above-described inner space. A portion of the display module DM is bent such that the flexible circuit film FCB and the main circuit board MCB face a rear surface of the display module DM, and may thus be accommodated in the housing EDC.

The housing EDC may include a material having a relatively high rigidity. For example, the housing EDC may include a frame and/or a plate containing glass, plastic, or metal, or composed of a combination thereof. The housing EDC may absorb an impact applied from the outside, or prevent infiltration of foreign substances/moisture, etc., from the outside, thereby protecting the display module DM, etc., accommodated in the housing EDC.

The cover window WM according to an aspect may be disposed on the display module DM and protect the display module DM against external impacts or scratches. The cover window WM may cover the entire outer side of the display module DM. A front surface of the cover window WM may correspond to an upper surface of the above-described electronic device EA.

The cover window WM according to an aspect may be divided into a transmission part TA and a bezel part BZA. The transmission part TA may be a part corresponding to the active region AA of the display module DM, and the bezel part BZA may be a part corresponding to the peripheral region NAA of the display module DM. The bezel part BZA may define a shape of the transmission part TA. The bezel part BZA may be adjacent to the transmission part TA and surround the transmission part TA. However, an aspect is not limited to what is illustrated in the drawing, and the bezel part BZA may either be disposed adjacent only to one side of the transmission part TA, or a part thereof may be omitted. The bezel part BZA of the cover window WM according to an aspect may have a relatively lower light transmittance than the transmission part TA.

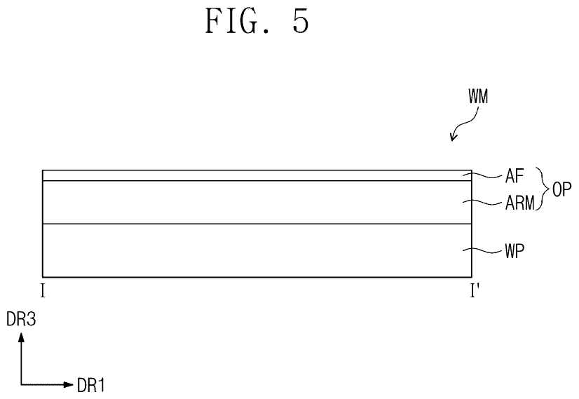

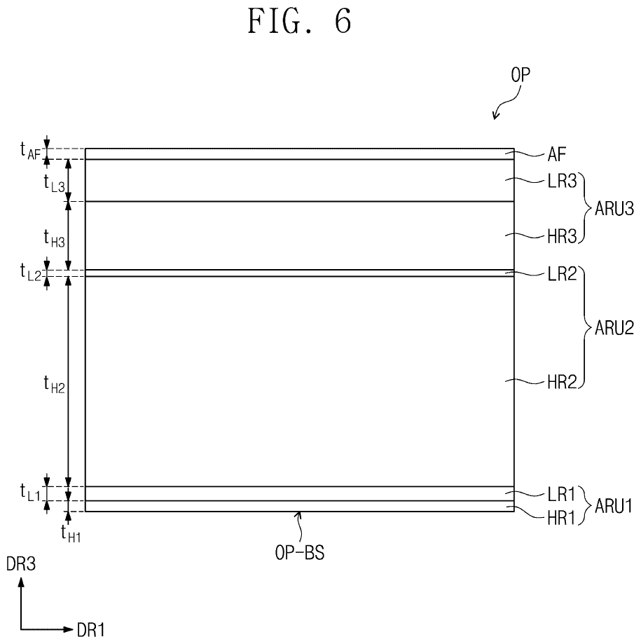

FIG. 5 is a cross-sectional view of a cover window according to an aspect, and FIG. 6 is a cross-sectional view of an optical member according to an aspect. FIG. 5 may be a cross-sectional view taken along line I-I′ of FIG. 4.

The cover window WM according to an aspect may include a base substrate WP which is formed of an optically transparent insulating material. The base substrate WP may include an optically transparent insulating material. The base substrate WP may include at least one of a glass substrate or a synthetic resin film. The base substrate WP may have a single-layered structure, or a multi-layered structure in which a plurality of films are coupled. The base substrate WP may be a glass substrate or a polymer substrate. For example, the base substrate WP may be a tempered glass substrate. In an aspect, an ultra-thin tempered glass substrate may be used for the base substrate WP of the cover window WM.

The cover window WM according to an aspect may include an optical member OP according to an aspect disposed on the base substrate WP. The optical member OP according to an aspect may function as a reflection reducing member which reduces reflectance for external light.

The optical member OP according to an aspect may include a reflection reducing layer ARM. The optical member OP according to an aspect may further include an anti-fingerprint layer AF disposed on the reflection reducing layer ARM. Additionally, the optical member OP according to an aspect may further include a functional layer such as a hard coating layer or an anti-pollution layer.

The cover window WM may further include an adhesive layer (not illustrated). The base substrate WP and the display module DM (see FIG. 4) may be bonded via the adhesive layer (not illustrated). However, the adhesive layer is not limited thereto, and may be omitted. The base substrate WP of the cover window WM may be directly disposed on the display module DM (see FIG. 4).

In this specification, it will be understood that the wording “being directly disposed” may mean that there are no intervening layers, films, regions, plates, etc. between a portion of layers, films, regions, plates, etc. and another portion. For example, the wording “being directly disposed” may mean to be disposed between two layers or two members without using an additional member such as an adhesive member.

The reflection reducing layer ARM may also be referred to as an anti-reflection layer. The reflection reducing layer ARM may function to reduce the amount of reflected light when light entering from the outside is reflected from the display module, etc. In an aspect, the reflection reducing layer ARM may effectively absorb or refract light within a wide wavelength range to reduce the amount of reflected light.

The optical member OP, according to an aspect, which includes the reflection reducing layer ARM, is disposed above the display module, etc. generating an image to reduce reflected light, and thus definition of an image provided by the display module may be enhanced. Additionally, color distortion caused by reflection is reduced, and it may be possible to improve a color sensitivity represented in a provided image.

Referring to FIG. 6, an optical member OP according to an aspect may include a plurality of stacked units ARU1, ARU2, and ARU3 which include high-refractive-index layers HR1, HR2, and HR3 and low-refractive-index layers LR1, LR2, and LR3, respectively. In the optical member OP according to an aspect, the low-refractive-index layers LR1, LR2, and LR3 of the stacked units may be directly disposed on the high-refractive-index layers HR1, HR2, and HR3, respectively.

The optical member OP according to an aspect may include three stacked units ARU1, ARU2, and ARU3. The three stacked units may be disposed to be sequentially stacked in a thickness direction.

Referring to FIG. 6, the optical member OP according to an aspect may include a first stacked unit ARU1, a second stacked unit ARU2, and a third stacked unit ARU3 sequentially disposed in the third direction DR3 which is the thickness direction. In an aspect, a lower surface OP-BS of the optical member OP may be a surface adjacent to a base substrate WP of a cover window WM.

The reflection reducing layer ARM of the optical member OP according to an aspect may have a structure in which a high-refractive-index layer and low-refractive-index layer are alternately stacked. In an aspect, the first stacked unit ARU1 may include a first high-refractive-index layer HR1 and a first low-refractive-index layer LR1 directly disposed on the first high-refractive-index layer HR1, the second stacked unit ARU2 may include a second high-refractive-index layer R2 and a second low-refractive-index layer LR2 directly disposed on the second high-refractive-index layer R2, and the third stacked unit ARU3 may include a third high-refractive-index layer HR3 and a third low-refractive-index layer LR3 directly disposed on the third high-refractive-index layer HR3. Additionally, in an aspect, the second high-refractive-index layer R2 may be directly disposed on the first low-refractive-index layer LR1, and the third high-refractive-index layer HR3 may be directly disposed on the second low-refractive-index layer LR2.

The high-refractive-index layers HR1, R2, and HR3, and the low-refractive-index layers LR1, LR2, and LR3 of the optical member OP according to an aspect may each be provided through a sputtering deposition method, or an E-beam evaporation method.

In an aspect, a difference between the refractive index of the high-refractive-index layers HR1, HR2, and HR3, and the low-refractive-index layers LR1, LR2, and LR3 may be about 0.3 or more. The refractive index of the low-refractive-index layers LR1, LR2, and LR3 may be lower than the refractive index of the high-refractive-index layers HR1, R2, and HR3 by about 0.3 or more.

In an aspect, the high-refractive-index layers HR1, HR2, and HR3 may have a refractive index of about 1.90 to about 2.30. In an aspect, the low-refractive-index layers LR1, LR2, and LR3 may have a refractive index of about 1.41 to about 1.54.

In an aspect, the high-refractive-index layers HR1, HR2, and HR3 may include an Al—Si—N nanocomposite material. The high-refractive-index layers HR1, HR2, and HR3 may be composite material layers which include aluminum (Al), silicon (Si), and nitrogen (N). The high-refractive-index layers HR1, R2, and HR3 may include an Al—Si—N nanocomposite material, and aluminum silicon oxynitride. The aluminum silicon oxynitride may be formed by the combination of a composite material and oxygen (O₂) which is introduced during the formation of the high-refractive-index layers HR1, HR2, and HR3.

The high-refractive-index layers HR1, HR2, and HR3, which include the Al—Si—N nanocomposite material, may be provided through a deposition method in which two targets of an Al target and a Si target are used and N₂ gas is provided. Additionally, the high-refractive-index layers HR1, R2, and HR3 may be provided through a deposition method in which an AlSi alloy target is used and N₂ gas is provided, alternatively.

The high-refractive-index layers HR1, HR2, and HR3, which include the Al—Si—N nanocomposite material, may have a Si content of about 5 at % to about 17 at %, where “at %” is atomic percentage. Additionally, the high-refractive-index layers HR1, R2, and HR3 may include O due to oxygen (O₂) which is introduced during a process. The high-refractive-index layers HR1, HR2, and HR3 may have an O content of less than about 20 at %.

In an aspect, the low-refractive-index layers LR1, LR2, and LR3 may include a silicon oxide (SiOₓ). For example, the low-refractive-index layers LR1, LR2, and LR3 may include SiO₂.

In the optical member OP according to an aspect, the second high-refractive-index layer HR2 of the second stacked unit ARU2 may have a thickness t_{H2} of about 250 nm to about 410 nm. For example, in an aspect, the second high-refractive-index layer HR2 may have a thickness t_{H2} of about 300 nm.

In an aspect, since the second high-refractive-index layer HR2 has the thickness t_{H2} of about 250 nm to about 410 nm, the optical member OP according to an aspect has excellent strength, excellent light transmittance, and low reflection properties, thereby making it possible to achieve reduction in color shift caused by the optical member OP. When the second high-refractive-index layer R2 of the second stacked unit ARU2 has a thickness t_{H2} of about 250 nm to about 410 nm, the optical member OP according to an aspect may exhibit a more transparent color tone. Therefore, the color distortion phenomenon that occurs when optical member OP is applied may be mitigated.

In an aspect, the first high-refractive-index layer HR1 of the first stacked unit ARU1 may have a thickness t_{H1} of about 15 nm to about 30 nm. Also, the first low-refractive-index layer LR1 of the first stacked unit ARU1 may have a thickness t_{L1} of about 18 nm to about 33 nm. For example, the first high-refractive-index layer HR1 may have a thickness t_{H1} of about 26.3 nm, and the first low-refractive-index layer LR1 may have a thickness t_{L1} of about 25.2 nm.

In an aspect, the second low-refractive-index layer LR2 of the second stacked unit ARU2 may have a thickness t_{L2} of about 5 nm to about 15 nm. For example, the second low-refractive-index layer LR2 may have a thickness t_{L2} of about 8.0 nm.

In an aspect, the third high-refractive-index layer HR3 of the third stacked unit ARU3 may have a thickness t_{H3} of about 130 nm to about 160 nm. Also, the third low-refractive-index layer LR3 of the third stacked unit ARU3 may have a thickness t_{L3} of about 72 nm to about 98 nm. For example, the third high-refractive-index layer HR3 may have a thickness t_{H3} of about 159.8 nm, and the third low-refractive-index layer LR3 may have a thickness t_{L3} of about 82.8 nm.

The optical member OP according to an aspect may exhibit not only a high strength but also excellent optical properties when the high-refractive-index layers HR1, R2, and HR3, and the low-refractive-index layers LR1, LR2, and LR3, of the first to third stacked units ARU1, ARU2, and ARU3, have thicknesses satisfying a combination of the above-described thickness ranges.

The optical member OP according to an aspect may further include an anti-fingerprint layer AF. The anti-fingerprint layer AF may be disposed on the uppermost stacked unit among the stacked units ARU1, ARU2, and ARU3. The anti-fingerprint layer AF may be disposed above the third stacked unit ARU3.

In an aspect, the anti-fingerprint layer AF may be disposed on the third low-refractive-index layer LR3 of the third stacked unit ARU3. For example, in an aspect, the anti-fingerprint layer AF may be directly disposed on the third low-refractive-index layer LR3 of the third stacked unit ARU3.

In an aspect, the anti-fingerprint layer AF may have a thickness t_{AF} of about 10 nm to about 30 nm. For example, the anti-fingerprint layer AF may have a thickness t_{AF} of about 20 nm.

The anti-fingerprint layer AF may include a fluorine compound. The anti-fingerprint layer AF may include a fluorine-based polymer.

In an aspect, the optical member OP may further include an intermediate layer between the anti-fingerprint layer AF and the third stack unit ARU3. The intermediate layer may be disposed between the third low-refractive-index layer LR3 of the third stack unit ARU3 and the anti-fingerprint layer AF, and includes a silicon oxide. The silicon oxide of the intermediate layer may have a columnar structure. The deposited silicon oxide film of the intermediate layer has a different structure from the planarization film of a silicon oxide included in the third low-refractive-index layer LR3 which is disposed below the intermediate layer. When the anti-fingerprint layer AF is provided on the reflection reducing layer ARM after the reflection reducing layer ARM is provided, the difference in such deposition film forms may occur due to use of different deposition apparatuses.

The three stacked units ARU1, ARU2, and ARU3 of which the high-refractive-index layers HR1, HR2, and HR3 and the low-refractive-index layers LR1, LR2, and LR3 have thicknesses satisfying a combination of ranges, may function as a reflection reduction member having a high hardness as well as excellent optical properties.

The cover window WM, according to an aspect, which includes the optical member OP according to an aspect may exhibit excellent surface strength and excellent optical properties.

The cover window WM according to an aspect may have the maximum hardness of about 15 GPa or more which is measured through the Berkovich indentation hardness test on the basis of an indentation depth of about 50 nm or more. The cover window WM according to an aspect has a hardness of about 15 GPa or more, and thus may have excellent impact resistance and strength.

The cover window WM according to an aspect may have an average transmittance of about 92% or more and an average Specular Component Included (SCI) reflectance of about 8% or less within a wavelength range of about 400 nm to about 700 nm. The cover window WM according to an aspect includes the optical member OP according to an aspect, may exhibit improved hardness and optical properties. For reference, the base substrate WP, which is a glass substrate and on which the optical member OP is not disposed, may have a hardness of about 7 GPa to about 10 GPa, and a transmittance of about 91% or less.

The cover window WM according to an aspect may have a color shift of about 2 or less. The color shift of the cover window WM is obtained by evaluating color change according to viewing angle. The cover window WM according to an aspect has a color shift of about 2 or less in the viewing angle range of 0° to about 60°, and the color shift may be calculated by the following equation 1.

$$color shift = \sqrt{{( {a}_{2}^{*} - {a}_{1}^{*} )}^{2} + {( {b}_{2}^{*} - {b}_{1}^{*} )}^{2}} \qquad ( Eq . 1 )$$

In the above-described equation 1, a*₁ and b*₁ each represent a LAB color coordinate for normally, e.g. 0°, incident light, and a*₂ and b*₂ each represent a LAB color coordinate for incident light according to a viewing angle. LAB is short for L*a*b* where L* represents lightness, a* represents a red/green coordinate value, and b* represents a blue/yellow coordinate value.

The cover window WM according to an aspect has a color shift value of about 2 or less within a viewing angle range of 0° to about 60°, and thus exhibits minimized color change when viewing angle is varied. Additionally, since the color change according to viewing angle is minimized, the cover window WM according to an aspect may have a transparent color tone.

The cover window WM according to an aspect may include the optical member OP including the three stacked units ARU1, ARU2, and ARU3 of which the high-refractive-index layers HR1, HR2, and HR3 and the low-refractive-index layers LR1, LR2, and LR3 have thicknesses satisfying a combination of ranges, thereby exhibiting excellent optical properties while maintaining a high hardness. Additionally, since no color of the optical member OP is observed, the cover window WM according to an aspect may exhibit more transparent color properties than a typical cover window.

The cover window WM according to this aspect may be included in the electronic device EA (see FIG. 3). The cover window WM may define an upper surface of the electronic device EA (see FIG. 3), protect a display module, etc. which constitute the electronic device EA (see FIG. 3), and minimize color distortion, etc. of an image provided by the display module. Additionally, the cover window WM according to an aspect may reduce light reflected from the display module DM (see FIG. 4), etc. Accordingly, the electronic device EA (see FIG. 3) according to an aspect may have excellent reliability due to a high-hardness upper surface as well as exhibit excellent display quality.

Table 1 below shows an optical member of Comparative Examples, and a layer structure of an optical member of Example. Table 1 shows thicknesses of respective layers of the optical members of Comparative Examples and Example. The optical members of Comparative Examples differ from the optical member of Example in that the thickness of the second high-refractive-index layer falls outside the above-described thickness range of about 250 nm to about 410 nm. It is understood that the second high-refractive-index layer of Comparative Example 1 has a thickness of about 454.2 nm, which is above the thickness range of the second high-refractive-index layer of Example, and the second high-refractive-index layer of Comparative example 2 has a thickness of about 44.2 nm, which is below the thickness range of the second high-refractive-index layer of Example. In Comparative Examples, remaining layers of the optical member fall within the thickness range of each layer of the optical member according to an aspect, and are within a thickness range similar to that of the optical member of Example.

TABLE 1

| | Optical | Optical | |
|---|---|---|---|
| | Member of | Member of | Optical |
| | Comparative | Comparative | Member of |
| Layer Structure | Example 1 | Example 2 | Example |
| Third Low-Refractive- | 86.5 | 88.1 | 82.8 |
| Index Layer Thickness | | | |
| (nm) | | | |
| Third High-Refractive- | 146.8 | 151.7 | 159.8 |
| Index Layer Thickness | | | |
| (nm) | | | |
| Second Low- | 9.9 | 22.8 | 8.0 |
| Refractive-Index | | | |
| Layer Thickness (nm) | | | |
| Second High- | 454.2 | 44.2 | 300.0 |
| Refractive-Index | | | |
| Layer Thickness (nm) | | | |
| First Low-Refractive- | 25.8 | 46.4 | 25.2 |
| Index Layer Thickness | | | |
| (nm) | | | |
| First High-Refractive- | 20.2 | 17.4 | 26.3 |
| Index Layer Thickness | | | |
| (nm) | | | |

Table 2 shows the evaluation results for the cover windows of Comparative Examples and Example in which the optical members, of Comparative Examples and Example, having the thicknesses shown in Table 1 are disposed on a glass substrate.

TABLE 2

| | | Comparative | Comparative | |
|---|---|---|---|---|
| Evaluation Items | | Example 1 | Example 2 | Example |
| Color Coordinate (a*, b*) | | 1.54, −6.95 | −0.21, −0.60 | −0.57, −1.42 |
| Color Shift | | | ≤2 | ≤2 |
| SCI | @ 550 nm | 4.9 | 4.62 | 4.7 |
| reflectance | @ 400 nm | 5.5 | 4.92 | 4.8 |
| (%) | to 700 nm | | | |

| | | | |
|---|---|---|---|
| Hardness (GPa) | 14.5 | 10.9 | 15.2 |
| Flatness (nm) | 0.200 | 0.066 | 0.052 |
| Residual Stress (GPa) | | | <2 |

Referring to the results in Table 2, it may be seen that the cover window of Example has an excellent hardness compared to the cover windows of Comparative Examples and exhibits excellent reflection reduction properties within a range of about 400 nm to about 700 nm which corresponds to a visible light range. Additionally, it may be seen that the cover window of Example has a more transparent color tone than that of Comparative Example 1 since the color coordinate of Example is closer to (0, 0) than that of Comparative Example 1. Furthermore, it may be confirmed that the cover window of Example has a thickness deviation of about 0.052 nm or less to exhibit a high flatness, and also maintains a low residual stress of about 2 GPa or less to ensure a high film stability for the optical member.

An optical member according to an aspect may include three stacked units, each of which includes a high-refractive-index layer and a low-refractive-index layer, and among which the high-refractive-index layer of the second stacked unit has a thickness of about 250 nm to about 410 nm, thereby exhibiting a high hardness as well as excellent optical properties. Additionally, the optical member according to an aspect may function as a low-reflection member which has not only a transparent color tone but also a small color shift when light is reflected.

A cover window according to an aspect may include an optical member including three stacked units, each of which includes a high-refractive-index layer and a low-refractive-index layer, and among which the high-refractive-index layer of a second stacked unit has a thickness of about 250 nm to about 410 nm, thereby exhibiting high hardness as well as excellent optical properties.

An electronic device according to an aspect may include a cover window which is disposed on a display module and includes an optical member including three stacked units, each of which includes a high-refractive-index layer and a low-refractive-index layer, and among which the high-refractive-index layer of a second stacked unit has a thickness of about 250 nm to about 410 nm, thereby exhibiting high strength which in turn contributes to excellent reliability and high-quality display performance.

An optical member according to an aspect may include a plurality of stacked units, each of which includes a high-refractive-index layer and a low-refractive-index layer, and in which the high-refractive-index layer and the low-refractive-index layer have thicknesses within optimized ranges, thereby not only maintaining excellent strength but also exhibiting a transparent color tone.

A cover window according to an aspect may include an optical member disposed on a base substrate, and including a plurality of stacked units, each of which includes a high-refractive-index layer and a low-refractive-index layer, and in which the high-refractive-index layer and the low-refractive-index layer have thicknesses within optimized ranges, thereby exhibiting excellent surface strength and improved optical properties.

An electronic device according to an aspect may include an optical member including a plurality of stacked units, each of which includes a high-refractive-index layer and a low-refractive-index layer, and in which the high-refractive-index layer and the low-refractive-index layer have thicknesses within optimized ranges, thereby exhibiting excellent strength and improved display quality.

In the above, description has been made with reference to aspects of the present disclosure, but those skilled or of ordinary skill in the art may understand that various modifications and changes may be made to the present disclosure insofar as such modifications and changes do not depart from the spirit and technical scope of the present disclosure.

Therefore, the technical scope of the present disclosure is not to be limited to the contents stated in the detailed description of the specification.

What is claimed is:

1. An optical member comprising three stacked units, each stacked unit includes a high-refractive-index layer and a low-refractive-index layer directly disposed on the high-refractive-index layer, the low-refractive-index layer having a refractive index lower than a refractive index of the high-refractive-index layer by about 0.3 or more,
wherein the three stacked units include a first stacked unit, a second stacked unit, and a third stacked unit which are stacked in a thickness direction, and
the high-refractive-index layer of the second stacked unit has a thickness of about 250 nm to about 410 nm.

2. The optical member of claim 1, wherein the high-refractive-index layer of each stacked unit comprises an Al—Si—N nanocomposite material, and
the low-refractive-index layer of each stacked unit comprises a silicon oxide.

3. The optical member of claim 2, wherein the high-refractive-index layer of each stacked unit has a Si content of about 5 at % to about 17 at %, and an O content of less than about 20 at %.

4. The optical member of claim 1, wherein the refractive index of the high-refractive-index layer of each stacked unit is about 1.90 to about 2.30.

5. The optical member of claim 1, wherein the refractive index of the low-refractive-index layer of each stacked unit is about 1.41 to about 1.54.

6. The optical member of claim 1, wherein the low-refractive-index layer of the first stacked unit is directly disposed on the high-refractive-index layer of the first stacked unit,
the high-refractive-index layer of the second stacked unit is directly disposed on the low-refractive-index layer of the first stacked unit, the low-refractive-index layer of the second stacked unit is directly disposed on the high-refractive-index layer of the second stacked unit,
the high-refractive-index layer of the third stacked unit is directly disposed on the low-refractive-index layer of the second stacked unit, and the low-refractive-index layer of the third stacked unit is disposed on the high-refractive-index layer of the third stacked unit,
the high-refractive-index layer of the first stacked unit has a thickness of about 15 nm to about 30 nm,
the low-refractive-index layer of the first stacked unit has a thickness of about 18 nm to about 33 nm,
the low-refractive-index layer of the second stacked unit has a thickness of about 5 nm to about 15 nm,
the high-refractive-index layer of the third stacked unit has a thickness of about 130 nm to about 160 nm, and
the low-refractive-index layer of the third stacked unit has a thickness of about 72 nm to about 98 nm.

7. The optical member of claim 1, further comprising an anti-fingerprint layer directly disposed on an uppermost stacked unit among the stacked units, and having a thickness of about 10 nm to about 30 nm.

8. The optical member of claim 1, wherein the optical member has a residual stress of about 2 GPa or less at room temperature.

9. A cover window comprising:
a base substrate; and
an optical member including a first stacked unit, a second stacked unit, and a third stacked unit which are sequentially stacked on the base substrate,
wherein the first to third stacked units each include a high-refractive-index layer, and a low-refractive-index layer directly disposed on the high-refractive-index layer, the low-refractive-index layer having an index of refraction lower than an index of refraction of the high-refractive-index layer by about 0.3 or more, and
the high-refractive-index layer of the second stacked unit has a thickness of about 250 nm to about 410 nm.

10. The cover window of claim 9, wherein the high-refractive-index layer of each stacked unit comprises an Al—Si—N nanocomposite material, and
the low-refractive-index layer of each stacked unit comprises a silicon oxide.

11. The cover window of claim 9, wherein the low-refractive-index layer of the first stacked unit is directly disposed on the high-refractive-index layer of the first stacked unit,
the high-refractive-index layer of the second stacked unit is directly disposed on the low-refractive-index layer of the first stacked unit, the low-refractive-index layer of the second stacked unit is directly disposed on the high-refractive-index layer of the second stacked unit,
the high-refractive-index layer of the third stacked unit is directly disposed on the low-refractive-index layer of the second stacked unit, and the low-refractive-index layer of the third stacked unit is disposed on the high-refractive-index layer of the third stacked unit,
the high-refractive-index layer of the first stacked unit has a thickness of about 15 nm to about 30 nm,
the low-refractive-index layer of the first stacked unit has a thickness of about 18 nm to about 33 nm,
the low-refractive-index layer of the second stacked unit has a thickness of about 5 nm to about 15 nm,
the high-refractive-index layer of the third stacked unit has a thickness of about 130 nm to about 160 nm, and
the low-refractive-index layer of the third stacked unit has a thickness of about 72 nm to about 98 nm.

12. The cover window of claim 9, wherein the refractive index of the high-refractive-index layer of each stacked unit is about 1.90 to about 2.30, and
the refractive index of the low-refractive-index layer of each stacked unit is about 1.41 to about 1.54.

13. The cover window of claim 9, wherein the cover window has a maximum hardness of about 15 GPa or more, where maximum hardness is measured using a Berkovich indentation hardness test on the basis of an indentation depth of about 50 nm or more.

14. The cover window of claim 13, wherein the cover window has an average transmittance of about 92% or more and an average SCI reflectance of about 8% or less within a wavelength range of about 400 nm to about 700 nm.

15. The cover window of claim 13, wherein the cover window has a color shift of about 2 or less for all viewing angles in a range of about 0° to about 60°, where the color shift is calculated by the following equation:
$$color shift = \sqrt{{( {a}_{2}^{*} - {a}_{1}^{*} )}^{2} + {( {b}_{2}^{*} - {b}_{1}^{*} )}^{2}}$$
where a*₁ and b*₁ each represents a LAB color coordinate for normally incident light at 0°, and a*₂ and b*₂ each represents a LAB color coordinate for incident light at a particular viewing angle.

16. An electronic device comprising:
a display module configured to generate an image; and
a cover window disposed on the display module,
wherein the cover window includes
a base substrate disposed adjacent to the display module, and
an optical member including a first stacked unit, a second stacked unit, and a third stacked unit which are sequentially stacked on the base substrate, and
the first to third stacked units each include a high-refractive-index layer, and a low-refractive-index layer directly disposed on the high-refractive-index layer, the low-refractive-index layer having an index of refraction lower than an index of refraction of the high-refractive-index layer by about 0.3 or more, and
the high-refractive-index layer of the second stacked unit has a thickness of about 250 nm to about 410 nm.

17. The electronic device of claim 16,
wherein the low-refractive-index layer of the first stacked unit is directly disposed on the high-refractive-index layer of the first stacked unit,
the high-refractive-index layer of the second stacked unit is directly disposed on the low-refractive-index layer of the first stacked unit, the low-refractive-index layer of the second stacked unit is directly disposed on the high-refractive-index layer of the second stacked unit,
the high-refractive-index layer of the third stacked unit is directly disposed on the low-refractive-index layer of the second stacked unit, and the low-refractive-index layer of the third stacked unit is disposed on the high-refractive-index layer of the third stacked unit,
the high-refractive-index layer of the first stacked unit has a thickness of about 15 nm to about 30 nm,
the low-refractive-index layer of the first stacked unit has a thickness of about 18 nm to about 33 nm,
the low-refractive-index layer of the second stacked unit has a thickness of about 5 nm to about 15 nm,
the high-refractive-index layer of the third stacked unit has a thickness of about 130 nm to about 160 nm, and
the low-refractive-index layer of the third stacked unit has a thickness of about 72 nm to about 98 nm.

18. The electronic device of claim 17, wherein the cover window has a maximum hardness of about 15 GPa or more, where maximum hardness is measured using a Berkovich indentation hardness test on the basis of an indentation depth of about 50 nm or more, and
the cover window has an average transmittance of about 92% or more and an average SCI reflectance of about 8% or less within a wavelength range of about 400 nm to about 700 nm.

19. The electronic device of claim 16, wherein the refractive index of the high-refractive-index layer of each stacked unit is about 1.90 to about 2.30, and the refractive index of the low-refractive-index layer of each stacked unit is about 1.41 to about 1.54.

20. The electronic device of claim 16, further comprising at least one of a power module, a processor, or a memory.
